(19) United States
(12) Patent Application Publication
(10) Pub. No.: US 2011/0183261 A1
(43) Pub. Date: Jul. 28, 2011

(54) DEVELOPER COMPOSITION

(75) Inventors: Yen-Cheng Li, Taoyuan (TW); Nai-Tien Chou, Taoyuan (TW)

(73) Assignee: EVERLIGHT USA, INC., Pineville, NC (US)

(21) Appl. No.: 12/721,108

(22) Filed: Mar. 10, 2010

(30) Foreign Application Priority Data
Jan. 28, 2010 (TW) 099102371

(51) Int. Cl. G03F 7/004

(52) U.S. Cl. 430/270.1

(57) ABSTRACT

A developer composition with low metal corrosiveness is provided. The developer composition includes 1 to 10 weight parts of tetraalkylammonium hydroxide; 0.01 to 3 weight parts of a metal corrosion inhibiting agent; 0.1 to 5 weight parts of a pH control agent; 0.1 to 5 weight parts of a surfactant; and water in balance. The developer composition of the present invention has a metal corrosion prevents corrosiveness to metals such as aluminum and copper during a resist development.

### FIELD OF INVENTION

The present invention relates to developer compositions for photoresists, and more particularly, to a developer composition with low metal corrosiveness for fabricating a semiconductor or a printed circuit board.

### BACKGROUND OF THE INVENTION

Optical lithography is a common technology in the fabrication of a semiconductor or a printed circuit board. A person skilled in the art understands that a lithographic process includes the following steps. To form a pattern on a substrate, a semiconductor wafer is coated with a liquid resist, and then baked to form a resist layer thereon. A pattern is formed on the resist layer via a photomask. A resist mask is obtained after performing a resist development of the pattern in a resist developer. The resist mask is used in subsequent processes. In some regions of the substrate, aluminum traces are formed by methods such as chemical vapor deposition (CVD) and sputtered coating, and copper traces are formed by a method such as electroplating. The above fabricating steps are repeated to form an electrical circuit of a semiconductor element.

The conventional developer compositions for a resist include widely used organic and inorganic alkali solutions, especially metal ion-free aqueous tetraalkylammonium hydroxide solutions.

Nevertheless, the aforesaid developer compositions are highly corrosive to aluminum and copper. Hence, the aforesaid developer compositions are not suitable for use in substrates formed with aluminum and copper traces.

There are a variety of studies on the inhibition of the corrosion of metals such as aluminum and copper caused by a developer. For example, JP3417432 discloses an anti-corrosive developer, which is prepared by blending 20 to 50 wt % of polyol as an corrosion inhibiting agent with a tetraalkylammonium hydroxide developer free of metal ions in the main ingredients thereof. Further, JP2003-330204 discloses an aqueous low metal corrosiveness developer composition, which includes 1 to 10 wt % of organic alkali, 1 to 10 wt % of carbohydrate and 1 to 10 wt % of polyol. However, these low metal corrosiveness developer compositions are still insufficient in anti-corrosiveness to metals such as aluminum and copper.

Accordingly, there exists an urgent need to develop a developer composition with low metal corrosiveness.

### SUMMARY OF THE INVENTION

The present invention provides a developer composition with low metal corrosiveness, which includes 1 to 10 weight parts of tetraalkylammonium hydroxide; 0.01 to 3 weight parts of a metal corrosion inhibiting agent; 0.1 to 5 weight parts of a pH control agent; 0.1 to 5 weight parts of a surfactant; and water in balance, wherein the weight parts are calculated based on 100 weight parts of the developer composition.

The developer composition of the present invention contains a metal corrosion inhibiting agent for preventing metal corrosion such as aluminum corrosion or copper corrosion caused by the developer composition during a resist development. The metal corrosion inhibiting agent also increases the ratio of the dissolution rate of an exposed portion of a resist to the dissolution rate of an unexposed portion of the resist, thereby maintaining good developing properties of the composition.

### DETAILED DESCRIPTION OF THE PREFERRED EMBODIMENTS

The following specific examples are used for illustrating the present invention. A person skilled in the art can easily conceive the other advantages and effects of the present invention.

The present invention provides a developer composition including tetraalkylammonium hydroxide; a metal corrosion inhibiting agent; a pH control agent; a surfactant; and water. The developer composition increases the ratio of the dissolution rate of an exposed portion of a resist to the dissolution rate of an unexposed region of the resist. Further, the developer composition is extremely poorly corrosive to metals such as aluminum and copper, thereby possessing good developing properties.

In the developer composition of the present invention, tetraalkylammonium hydroxide is in an amount ranging from 1 to 10 weight parts, preferably 1 to 5 weight parts, based on 100 weight parts of the developer composition. For example, tetraalkylammonium hydroxide can be tetramethyl ammonium hydroxide (TMAH) or tetrabutyl ammonium hydroxide (TBAH). In an embodiment, TMAH is used.

In the developer composition of the present invention, the metal corrosion inhibiting agent is in an amount ranging from 0.01 to 3 weight parts, and preferably 0.05 to 1 weight part based on 100 weight parts of the developer composition. For example, the metal corrosion inhibiting agent can be an aryl conjugate acid metal salt or an amine compound substituted by one or more substituents, wherein the substituents are each selected from C₁-C₆ alkyl and hydroxyalkyl containing 1 to 6 carbon atoms. Specifically, the metal corrosion inhibiting agent can be selected from the group consisting of hexamethylenetetramine, monoethanolamine and sodium benzoate, wherein monoethanolamine and sodium benzoate have the better effects.

Moreover, the pH control agent is in an amount ranging from 0.1 to 5 weight parts, and preferably 0.1 to 3 weight parts, based on 100 weight parts of the developer composition. The pH control agent can be an ammonium salt, for example ammonium carbonate ((NH₄)₂CO₃) and ammonium sulfate ((NH₄)₂SO₄), wherein ammonium sulfate has better effects. Further, the surfactant is in an amount ranging from 0.1 to 5 weight parts, and preferably 0.1 to 3 weight parts, based on 100 weight parts of the developer composition. There are no limitations to the types of surfactants used in the present invention. In a preferred embodiment, the surfactant is an alkyl diphenyl oxide disulfonate surfactant. Specifically, the surfactant has the following formula (I):

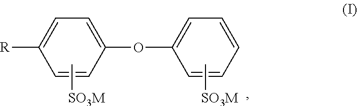

wherein R is a linear or branched C₄-C₂₀ alkyl, and M is H, NH₄ or an alkali metal element.

In a preferred embodiment, the surfactant is one selected from the group consisting of dodecyl diphenyl ether disulfonic acid, potassium dodecyl diphenyl ether disulfonate, ammonium dodecyl diphenyl ether disulfonate, sodium dodecyl diphenyl ether disulfonate (product names: Pelex SS-L and Pelex SS-H, manufactured by Kao Chemicals).

In addition to the above ingredients, the remaining ingredient of the developer composition, such as water, is used as a substrate for preparing the developer composition into 100 weight parts. The water can be pure water, de-ionized water or distilled water.

The present invention is further illustrated in detail by the following examples.

### EXAMPLES

### Preparation of a Developer Composition

According to Table 1, the developer compositions of Examples 1-4 and Comparative Example 1 were prepared. Each of the developer compositions was obtained by mainly mixing and formulating 3 g of tetraalkylammonium hydroxide, 0.1 g of a metal corrosion inhibiting agent, 0.5 g of ammonium sulfate ((NH₄)SO₄) as a pH control agent, 0.75 g of Kao Pelex SS-L as a surfactant, and 95.75 g of pure water.

TABLE 1

| | | | | | | Comparative |
|---|---|---|---|---|---|---|
| Ingredients | | Example 1 | Example 2 | Example 3 | Example 4 | Example 1 |
| Alkali | TMAH (g) | 3.00 | 3.00 | 3.00 | 3.00 | 3.00 |
| Surfacant | Kao Pelex SS-L (g) | 0.75 | 0.75 | 0.75 | 0.75 | 0.75 |
| pH control agent | (NH₄)₂SO₄ (g) | 0.50 | 0.50 | 0.50 | 0.50 | 0.50 |
| Pure water | Pure water (g) | 95.65 | 95.65 | 95.65 | 95.65 | 95.75 |
| Metal corrosion | hexamethylenetetramine | 0.10 | — | — | — | — |
| inhibiting agent | Monoethanolamine | — | 0.1 | — | — | — |
| | Sodium benzoate | — | — | 0.1 | — | — |
| | Triethanolamine | — | — | — | 0.1 | — |
| | — | — | — | — | — | — |

The surfactant (product name: Pelex SS-H, manufactured by Kao Chemicals) is sodium dodecyl diphenyl ether disulfonate, which has the following formula (I):

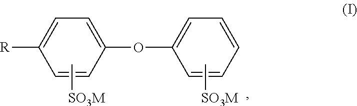

wherein R is C₁₂H₂₅, and M is Na.

### Test Example

### Evaluation of the Metal Corrosion Inhibition

### (1) Test on a Wafer Having an Aluminum Coating

At 25° C., a 4-inch silicon wafer formed with a 100 nm-thick aluminum coating thereon (i.e., a wafer shielded by a mono-layered coating) was immersed in one of the developer compositions prepared in accordance with the components and amount shown in Table 1, for 10 minutes. Then, the silicon wafer was removed from the developer composition, washed with pure water, and blown dry with an air gun supplying N₂ gas. After the silicon wafer dried, the surface roughness Rq (nm) of the aluminum coating of the silicon wafer was examined by an atomic force microscope (AFM, model type: DI3100, manufactured by VEECO).

### (2) Test on a Wafer Having a Copper Coating

At 25° C., a 4-inch silicon wafer formed with a 100 nm-thick copper coating thereon (i.e., a wafer shielded by a mono-layered coating) was immersed in one of the developer compositions prepared in accordance with the components and amount shown in Table 1, for 10 minutes. Then, the silicon wafer was removed from the developer composition, washed with pure water, and blown dry with an air gun supplying N₂ gas. After the silicon wafer dried, the surface roughness Rq (nm) of the copper coating of the silicon wafer was examined by an atomic force microscope (AFM, model type: DI3100, manufactured by VEECO).

### (3) Blank Test on a Wafer Having an Aluminum Coating

A 4-inch silicon wafer formed with a 100 nm-thick aluminum coating thereon (i.e., a wafer shielded by a mono-layered coating) was washed with pure water, and blown dry with an air gun supplying N₂ gas. After the silicon wafer dried, the surface roughness Rq (nm) of the aluminum coating of the silicon wafer was examined by an atomic force microscope (AFM, model type: DI3100, manufactured by VEECO).

### (4) Blank Test on a Wafer Having a Copper Coating

A 4-inch silicon wafer formed with a 100 nm-thick copper coating thereon (i.e., a wafer shielded by a mono-layered coating) was washed with pure water, and blown dry with an air gun supplying N₂ gas. After the wafer dried, the surface roughness Rq (nm) of the copper coating of the silicon wafer was examined by an atomic force microscope (AFM, model type: DI3100, manufactured by VEECO).

TABLE 2

| | Blank test | Blank test | | | | | |
|---|---|---|---|---|---|---|---|
| | (aluminum | (copper | Comparative | | | | |
| Rq (nm) | coating) | coating) | Example 1 | Example 1 | Example 2 | Example 3 | Example 4 |
| Surface | 4.014 | — | 4.712 | 3.144 | 3.956 | 3.104 | 3.216 |
| Roughness of | | | | | | | |
| Aluminum | | | | | | | |
| Coating | | | | | | | |
| Surface | — | 2.072 | 2.839 | 2.206 | 2.746 | 2.081 | 2.346 |
| Roughness of | | | | | | | |
| Copper | | | | | | | |
| Coating | | | | | | | |

As shown in Table 2, the developer composition of the present invention indeed inhibits the metal corrosion such as aluminum corrosion and copper corrosion caused by an alkaline developer composition.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

What is claimed is:

1. A developer composition, comprising:
1 to 10 weight parts of tetraalkylammonium hydroxide;
0.01 to 3 weight parts of a metal corrosion inhibiting agent;
0.1 to 5 weight parts of a pH control agent;
0.1 to 5 weight parts of a surfactant; and
water in balance, based on 100 weight parts of the developer composition.

2. The developer composition of claim 1, wherein the metal corrosion inhibiting agent inhibits at least one of aluminum corrosion and copper corrosion.

3. The developer composition of claim 1, wherein the metal corrosion inhibiting agent is one of an aryl conjugate acid metal salt and an amine compound substituted by one or more substituents, and wherein the substituents are each selected from C₁-C₆ alkyl and hydroxyalkyl.

4. The developer composition of claim 3, wherein the metal agent is at least one selected from the group consisting of hexamethylenetetramine, monoethanolamine, triethanolamine and sodium benzoate.

5. The developer composition of claim 1, wherein the pH control agent is one selected from the group consisting of ammonium carbonate ((NH₄)₂CO₃), ammonium sulfate ((NH₄)₂SO₄) and a combination thereof.

6. The developer composition of claim 1, wherein the pH control agent is ammonium sulfate ((NH₄)₂SO₄).

7. The developer composition of claim 1, wherein the surfactant is a diphenyl oxide disulfonate surfactant.

8. The developer composition of claim 7, wherein the surfactant has the following formula (I): 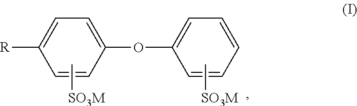
wherein R is a linear or branched C₄-C₂₀ alkyl, and M is H, NH₄ or an alkali metal element.

9. The developer composition of claim 7, wherein the surfactant is one or more selected from the group consisting of dodecyl diphenyl ether disulfonic acid, potassium dodecyl diphenyl ether disulfonate, ammonium dodecyl diphenyl ether disulfonate and sodium dodecyl diphenyl ether disulfonate.

10. The developer composition of claim 9, wherein the surfactant is sodium dodecyl diphenyl ether disulfonate.
